(19) United States
(12) Patent Application Publication
(10) Pub. No.: US 2011/0069731 A1
(43) Pub. Date: Mar. 24, 2011

(54) SCALABLE THERMALLY EFFICIENT PUMP DIODE ASSEMBLIES

(76) Inventor: M. Cem GOKAY, Centerville, OH (US)

(21) Appl. No.: 12/887,453

(22) Filed: Sep. 21, 2010

Related U.S. Application Data
(60) Provisional application No. 61/244,400, filed on Sep. 21, 2009.

(51) Int. Cl. H01S 5/00; H01L 21/00

(52) U.S. Cl. 372/45.01; 372/50.12; 438/22; 438/34; 257/E21.001

(57) ABSTRACT

Scalable, thermally efficient pump diode systems. These systems may include a first substrate having a plurality of grooves in alignment with a second substrate having a plurality of grooves. A first single emitter diode laser (“emitter”) may be disposed between the first substrate and the second substrate and aligned between two of the plurality of such grooves. Additional emitters or spacers may be disposed adjacent the first emitter such that at least one groove separates the elements (emitters/spacers). The grooves, which may comprise shallow scribes, channels, and/or other isolation structures, provide electrical isolation between adjacent emitters and/or spacers. A conductive layer may be disposed between the emitter(s) and the substrate(s), in electrical contact with each emitter, to provide power for operation of the emitters. A plurality of such assemblies, in a one-dimensional or a two-dimensional configuration, may be mounted, in a parallel or serial electrical power drive arrangement, adjacent a lasing medium to improve heat removal and/or to provide more efficient excitation of the medium.

### CROSS-REFERENCE

This application is based upon and claims the benefit under 35 U.S.C. §119(e) of U.S. Provisional Patent Application Ser. No. 61/244,400, filed Sep. 21, 2009, which is incorporated herein by reference in its entirety for all purposes.

### INTRODUCTION

Lasers are devices that use a quantum mechanical effect, stimulated emission, to generate light. This light may be produced in continuous or pulsed modes and typically is intense, coherent, monochromatic, and directional. Lasers create light using a lasing medium capable of population inversion, a condition in which the rate of optical amplification—i.e., spontaneous photon emission followed by stimulated emission—exceeds the rate at which photons are absorbed by the medium. To attain population inversion, the atoms of the lasing medium generally must be excited by an external energy source. Excitation of a lasing medium typically begins with pumping by an external optical source, which may be tuned to excite one or more particular atomic transitions in the medium. In other words, the pump may be designed to output most or all of its light to match the absorption spectrum of the lasing medium, because any energy emitted by the pump and not absorbed by atoms within the medium is wasted. The absorption spectrum of the lasing medium may be discrete, requiring a particular wavelength to excite atoms from the ground state to a desired excited state, or it may be continuous, allowing absorption of a range of wavelengths to produce the desired excitation. A number of different types of optical pumps have been developed with these different possibilities in mind.

Flash lamps and arc lamps having emission spectra that peak at appropriate wavelengths may be used for pumping a laser. Such lamps may be constructed from sealed tubes containing noble gases, such as krypton or xenon, and may have dimensions and/or shapes designed to match the dimensions of the lasing medium. These lamps generally have emission spectra that include several sharp peaks, one or more of which is chosen to coincide with the absorption spectrum of the lasing medium. However, other emission peaks typically will lie outside this absorption spectrum, which can lead to significant energy losses.

Incandescent lamps, such as tungsten filament bulbs, also may be used for pumping a laser. Such lamps generally emit a blackbody spectrum of radiation, which is a continuous spectrum that peaks at a particular wavelength determined by the temperature of the filament. Such a continuous spectrum may lead to substantial energy losses due to large amounts of radiation falling outside the absorption band of the laser. Although these losses can be minimized by carefully choosing the temperature of the filament such that the bulb's emission spectrum peaks near the center of the lasing medium's absorption band, and are further mitigated by the relatively low cost of the incandescent pump, they may be significant in many applications.

Laser diodes that produce radiation at approximately or precisely the desired excitation wavelength also may be used for pumping a laser. In other words, a first laser system, or pumping laser system, may be used to pump the lasing medium, also referred to as the gain medium, of a second laser system, or pumped laser system. Due to the effect of optical amplification described above, the pumped laser may have much greater peak intensity than the pumping laser. Because the laser diodes in diode-pumped systems are typically designed to produce radiation of a wavelength that matches a discrete peak of the gain medium's absorption spectrum, such systems may be highly efficient. Furthermore, high-density arrays of laser diodes in a pump system may more readily exceed the minimum required energy output to attain population inversion in the gain medium.

Despite the potentially high efficiency of laser diode pumping systems, they may also be subject to various undesirable effects, including inefficiency due to loss or lack of diode energy (or number of single emitter diodes (diode bars), per unit area-energy density), creation of isolated regions of excitement (“hot spots”) within the lasing/gain medium, overheating of the diode pumps, uneven mechanical stress on the laser, and/or undesirably large temperature gradients between the diodes and the adjacent mounting surface, among others. These effects may result from inadequate cooling of the system. For example, overheating of a diode pump may lead the pump system's output to drop below the minimum energy output to attain population inversion. Likewise, inadequate heat removal from a particular diode or set of diodes may lead to non-uniform excitation of the gain medium. Cooling may be especially challenging in high-density diode arrays in which laser diodes operate in proximity to one another. Accordingly, diode array density and pump system energy uniformity may be limited by the thermal characteristics of the system.

Therefore, laser diode pump systems are typically designed with cooling systems that attempt to minimize temperature instability and consequently improve performance of the system. For example, U.S. Pat. No. 7,529,286 to Gokay et al. (which is incorporated herein by reference in its entirety for all purposes) teaches laser diodes coupled with thermally conductive spacers to form diode/spacer blocks, in which the spacers are disposed between and in contact with the diode bars and conduct heat away from the diodes. Additionally, as further described in U.S. Pat. No. 7,529,286, a diode/spacer block may be mounted on a thermally conductive substrate attached to one or more external heat sinks. These external heat sinks may be cooled, for example, with air or with water.

However, mounting a diode emitter or multi emitter bar or multi-bar diode block to an external heat sink block or system requires matching coefficients of thermal expansion of the block and the heat sink, or use of a stress-absorbing solder, cascading materials, all of which may require tradeoffs of cost or reliability. Additionally, an external heat sink typically requires a large footprint, which effectively limits the number of diodes per unit area and therefore limits the energy density of the pumping system. Thus, a space-efficient and sufficiently thermally conductive heat sink system may be advantageous for high energy density laser diode pumping systems.

### SUMMARY

The present disclosure provides scalable, thermally efficient pump diode systems. These systems may include a first substrate having a plurality of grooves in alignment with a second substrate having a plurality of grooves. A first single emitter diode laser (“emitter”) may be disposed between the first substrate and the second substrate and aligned between two of the plurality of such grooves. Additional emitters or spacers may be disposed adjacent the first emitter such that at least one groove separates the elements (emitters/spacers). The grooves, which may comprise shallow scribes, channels, and/or other isolation structures, provide electrical isolation between adjacent emitters and/or spacers. A conductive layer may be disposed between the emitter(s) and the substrate(s), in electrical contact with each emitter, to provide power for operation of the emitters. A plurality of such assemblies, in a one-dimensional or a two-dimensional configuration, may be mounted, in a parallel or serial electrical power drive arrangement, adjacent a lasing medium to improve heat removal and/or to provide more efficient excitation of the medium.

### BRIEF DESCRIPTION OF THE DRAWINGS

FIG. 1 is an isometric view of a pump diode assembly including a single emitter, in accordance with aspects of the present disclosure.

FIG. 2 is a cross-sectional view of the pump diode assembly of FIG. 1, taken generally along line 2-2 in FIG. 1.

FIG. 3 is a series of configurations produced during manufacture of the pump diode assembly of FIG. 1, in accordance with aspects of the present disclosure.

FIG. 4 is a cross-sectional view of a pump diode assembly including a linear array of ten (10) emitters, connected in series, in accordance with aspects of the present disclosure.

FIG. 5 is a cross-sectional view of a pump diode assembly including a linear array of ten (10) emitters, connected in parallel, in accordance with aspects of the present disclosure.

FIG. 6 is an isometric view of the pump diode assembly of FIG. 1, shown in association with a fluid channel, in accordance with aspects of the present disclosure.

FIG. 7 is an isometric view of a pump diode assembly including a two-dimensional array of emitters, shown in association with a plurality of fluid channels and interfaced with a suitable gain medium, in accordance with aspects of the present disclosure.

FIG. 8A is an isometric view of a pump diode assembly multiplex, in accordance with aspects of the present disclosure.

FIG. 8B is a side view of the pump diode assembly multiplex of FIG. 8A, coupled to a lasing medium fiber and cooling system, in accordance with aspects of the present disclosure.

### DETAILED DESCRIPTION

The present disclosure relates to a scalable, high-density, thermally efficient single emitter, or multiplexing single emitter, laser diode module and method of manufacturing the same. The pump diode modules (also referred to as pump diode assemblies and/or pump diode bars) may be used to excite a lasing medium in a diode pumped laser system, among other applications. A scalable pump diode assembly for a diode pumped laser may include a first substrate having a plurality of grooves in alignment with a second substrate having a plurality of grooves. A first single emitter diode laser, referred to herein after as a first emitter, may be disposed between the first substrate and the second substrate and aligned between two of the plurality of grooves. Additional emitters or spacers may be disposed adjacent the first emitter such that at least one groove separates the elements (emitters/spacers). The grooves, which may comprise shallow scribes, channels, and/or other isolation structures, provide electrical isolation between adjacent emitters and/or spacers. A conductive layer may be disposed between the emitter(s) and the substrate(s), in electrical contact with each emitter, to provide electrical drive power for operation of the emitters.

A plurality of such assemblies, in a one-dimensional or a two-dimensional configuration, may be mounted, in a parallel or serial arrangement, adjacent a lasing medium to improve heat removal and/or to provide more efficient excitation of the medium. Such arrangements may increase power output from the laser by enhancing heat removal and/or excitation of the lasing medium. Moreover, such arrangements may increase the uniformity in temperature experienced by the pump diodes, and so lead to a more monochromatic light output, which in turn can lead to more efficient pumping and/or to more monochromatic output by the associated laser system.

The components of these various systems may be scalable, i.e., usable with different numbers, sizes, and/or shapes of diode emitters (such as higher power emitters having a longer cavity) and/or spacers in the diode assemblies, and so on. These and other aspects of the present disclosure are described below, in more detail, including but not limited to (I) an overview of the system, including (A) pump diode emitters, (B) thermally conductive spacers, and (C) substrates, and (II) examples of various pump diode assemblies, and diode pumped laser systems, among others.

### I. OVERVIEW

A laser system may include (1) one or more pump diode assemblies, capable of generating light, and (2) a lasing medium, capable of excitation by the light created by the diode assemblies, and capable of generating laser light. The diode assemblies, in turn, may include (1) one or a plurality of pump diodes (or single emitter(s) forming diode bar(s) or array of diode emitters forming diode bar(s) or single diode emitter(s)), (2) one or a plurality of thermally conductive spacers, disposed in proximity to and/or separating the pump diodes, (3) at least one substrate for receiving the pump diodes and/or conductive spacers; and/or (4) a plurality of grooves, also referred to as divots and/or guide holes, etched into the substrate such that one of the plurality of pump diodes is adjacent a groove on one or more sides. These and other aspects of the present disclosure are described below, in more detail.

I.A. Emitters

Emitters, as used herein, include light-emitting single emitter diode lasers capable of producing light. This light may be have a single wavelength, or a range of wavelengths, and may be directed in a narrow beam, or over a broader range of angles. Emitters may be selected that emit a desired wavelength within the absorption range of the lasing medium used in an associated diode pumped laser system. For example, emitters may be selected that emit radiation having wavelengths falling within a range of about 600-1550 nanometers (nm), to excite an atomic transition from the ground state to a suitable excited state in a lasing medium, such as a four-level, or greater than four-level, lasing medium. In the specific case of a lasing medium constructed from yttrium aluminum garnet doped with neodymium ions (known as Nd:YAG), emitters may be selected that emit radiation having one or more wavelengths falling within the range from 700-900 nm, or specifically that emit radiation at or around 808 nm, corresponding to one or more prominent absorption bands of Nd:YAG, or to allow efficient operation for broad operating temperatures, reducing or eliminating the need for inefficient temperature cooling devices, such as thermoelectric coolers (TECs), water, etc. More generally, emitters or diode bars may be selected to emit one or more wavelengths most appropriately matched to the absorption spectrum of any chosen lasing medium. The diode bars may include a single emitter laser diode, or a plurality of single emitter laser diodes, for example, in any suitable arrangement (such as a one-dimensional array or a two-dimensional array).

I.B. Spacers

Spacers (or thermally conductive spacers), as used herein, include spacing members that may be disposed adjacent to and/or separate components of diode assemblies (including emitters, substrates, and diode bars). These spacers, which are described below or convenience in the context of separating emitters, may be constructed from any suitable material(s), such as a high thermal conductivity material, to conduct heat away from the emitters and/or the lasing medium. Exemplary materials may include gold, copper, copper tungsten alloy, and/or diamond, among others. The choice of spacer material(s) may depend, for example, on factors such as the thermal coefficient of expansion, cost of the material, the number of emitters, the power output of the emitters, and/or the power output of the laser system, among others. The number of conductive spacers used may depend on some or all of these same factors. There may be one spacer between the outermost emitters and the substrate.

The spacers may be coated, in some embodiments, with suitable material(s), such as metallic solder (or other deposition), to provide an electrically conductive path between the emitters and the spacers. This may be particularly appropriate, for example, in embodiments in which the spacer material is a good thermal conductor, but a relatively poor electrical conductor. For instance, many forms of diamond have extremely high thermal conductivity, making diamond a good spacer material choice with regard to its ability to conduct heat away from the lasing medium and/or emitters. However, diamond typically also is a relatively poor electrical conductor, so that the use of bare diamond spacers may make it difficult to supply electrical current to the emitters by applying a voltage across the emitter/spacer array. Coating the diamond spacers with an electrically conducting material such as gold, silver, and/or other metallic solder provides one possible solution to this difficulty. Other solutions may include supplying power to each emitter independently and/or creating a conducting path across the emitter/spacer array in some other suitable manner, such as with a conducting liquid or with a solid conducting strip constructed from a material such as copper and/or gold.

I.C Substrates

Substrates, as used herein, include support for the arrangements of emitters, spacers, and/or diode arrays. Substrates may serve as and form the interface to a heat extraction medium of the pump diode assembly. The heat extraction medium may be metal, air, thermoelectric cooler (TEC), and/or liquid, such as water or others.

Typically, the substrate will include at least one groove and/or a plurality of grooves spanning a length of the substrate. The grooves may have any suitable width. Typically, to increase the fill factor, the width of the grooves may be less than the width of the emitter(s). The area of substrate surface between the plurality of grooves may be configured to receive the emitter(s) and/or spacer(s). For example, the area of substrate surface between the grooves may be substantially planar and/or have the same approximate width as the emitter(s) and/or spacer(s). Additionally and/or alternatively, the area of substrate surface between the plurality of grooves may include a conductive layer of suitable material(s), such as metallic solder (or other deposition), to provide an electrically conductive path between (across) the emitters, spacers, grooves and/or substrates.

Some embodiments of a pump diode assembly may include more than one substrate and/or more than one substrate having a plurality of grooves such that the pluralities of grooves of each substrate are in alignment. The grooves may provide electrical isolation, also referred to as a guide channel, between the emitters and/or spacers and/or may be filled with an insulating and/or adhesive material, also referred to as a guide filler. The guide channel and/or guide filler material may be a fiber-like, non-metallic material. In some embodiments, and unlike the substrate surface in contact with elements (emitters/spacers), the side walls of the groove may not have a conductive layer.

The substrates may be constructed in any suitable manner. In some cases, the substrates may be constructed unitarily (i.e., from a single piece of substrate material). In other cases, the substrates may be constructed from two, three, or more sections of material, also known as base members or components, configured to fit together. In yet other cases, the substrates may be constructed integrally or unitarily with one or more spacers.

The substrates may be constructed from any suitable material(s). Exemplary materials may be thermally conductive but electrically nonconductive, or nearly so, such as aluminum nitrate, beryllium oxide (BeO), and/or diamond, among others. Alternatively, exemplary materials may be both thermally and electrically conductive, or nearly so, such as metals, including copper, copper tungsten alloy, gold, tungsten, and/or various metal alloys, among others. Thermally conductive materials may facilitate conducting heat away from the pump diodes and/or lasing medium. Electrically conductive materials may facilitate conducting electricity to and from the emitters, for example, to power the emitters.

The substrates, like the emitters and spacers, may be coated and/or plated with a conductive layer with suitable material(s), such as metallic solder (or other deposition), to provide an electrically conductive path between (across) the emitters, spacers, grooves and/or substrates. In some embodiments, the conductive layer may comprise strip(s) of conductive material and/or discrete conductive area(s).

I.D. Pump Diode Assemblies

The emitters, spacers, and substrates described above may be combined to form pump diode assemblies, such as single emitter diode assemblies (see, e.g., Examples 1, 2, and 4), one-dimensional diode array assemblies (see, e.g., Example 3), and two-dimensional diode array assemblies (see, e.g., Example 5), among others. The pump diode assemblies may include pluralities of elements (pump diodes and/or spacers), together with one or more substrates. The pump diode assemblies, in turn, may be combined with suitable lasing media, such as a lasing medium rod, slab, and/or fiber, to form a diode pumped laser system.

The number, nature, dimensions, and arrangement of the different components used in the pump diode assemblies, and/or diode pumped laser systems, may be chosen based on a variety of criteria. For example, the pump diodes and lasing medium may be selected such that the pump diodes are capable of exciting, or pumping, the lasing medium. Similarly, the spacers may be selected to be electrically conducting or nonconducting based on whether the pump diodes are powered by electricity received through the spacers or through wires, respectively.

The components of these assemblies and systems typically will have complementary sizes. For example, depending on the output power or the energy of the single emitters, typical single emitter formed diode bars each may have a thickness or a width of between approximately 100 μm and 500 μm (0.1 mm-0.5 mm), or wider. (Here, 1 μm is 10⁻⁶ meters (a micrometer or micron), and 1 mm is 10⁻³ meter (a millimeter).) Conductive spacers each may have the same or different dimensions, such as thickness or width, as the emitters. The flexibility and scalability of the system may be enhanced when emitters and spacers have the same dimensions, making them interchangeable. The grooves within the substrate and/or the distance between a plurality of emitters and/or spacers may have a width or a thickness of between approximately 100 μm and 150 μm. Thus, a two-dimensional arrangement of X/Y (9×9) array of nine 100 μm wide×100 μm thick emitters and nine same-sized spacers may have a total size of approximately 1.9 mm by 1.9 mm, forming a 9×9 two-dimensional X/Y array with 50% fill factor. In accordance with the present disclosure, the same total sized X/Y array may have an increased fill factor, for example, 80%, by substituting one or more of spacers with emitters.

The length, or longest dimension, of the emitters and/or spacers may be chosen approximately to match the length of the lasing medium in a given system, or fiber coupling imaging system constraints, or some integer fraction thereof. In some embodiments, length may be approximately 1 mm, 3 mm, 9 mm, or much longer. The thickness, width, length, and/or depth, of the emitters and spacers may be chosen based on considerations including the overall dimensions of the system, the availability of suitable premanufactured single emitter diode lasers, and/or the cooling efficiency of a particular choice of dimensions. In general, the length, thickness, and depth of each spacer will be chosen at least partially based upon the size of suitable pre-manufactured single emitter diode lasers.

The length of the substrate may be chosen to be longer than that of the emitters and/or spacers such that the substrate extends beyond all sides of an emitter and/or diode bar or the opposite end along the emitter illumination axis. This additional substrate length, also referred to as substrate blade, extending beyond the diode unit may aid in dissipating heat generated by the diode unit (module) by conducting heat away from the diodes. Furthermore, the blades may be cooled by air or water, dissipating additional heat and generally improving temperature stability of the system. Two or more blades in a pump diode assembly may form cooling fluid channels, through with fluid may flow to cool the blades and thus the assembly. Additionally and/or alternatively, these extending blades may be used as electrode attachments (as described in Example 6).

The pump diode assemblies may be combined in various numbers and arrangements, such as single diode, series or parallel linear (one-dimensional) array and/or series or parallel X/Y (two-dimensional) array configurations.

### II. EXAMPLES

The following examples describe selected aspects of the present disclosure, including, among others, (1) exemplary pump diode assemblies having at least one emitter, (2) exemplary methods of manufacturing pump diode assemblies, (3) exemplary pump diode assemblies having a plurality of emitters in serial or parallel linear configurations, (4) exemplary pump diode assemblies, particularly with a single or at least one emitter and an extended substrate blade; and (5) exemplary pump diode assemblies having serial or parallel two-dimensional single emitter based (X/Y) array configurations and extended substrate blades. These examples and the various features and aspects thereof are included for illustration and are not intended to define or limit the entire scope of the present disclosure. Properties of components—single emitter diode lasers, diode bars, spacers, substrates, and conductive layers—of these exemplary systems, including sizes, shapes, functions, and compositions, are described above, in Section I.

### Example 1

### Pump Diode Assembly with at Least One Emitter

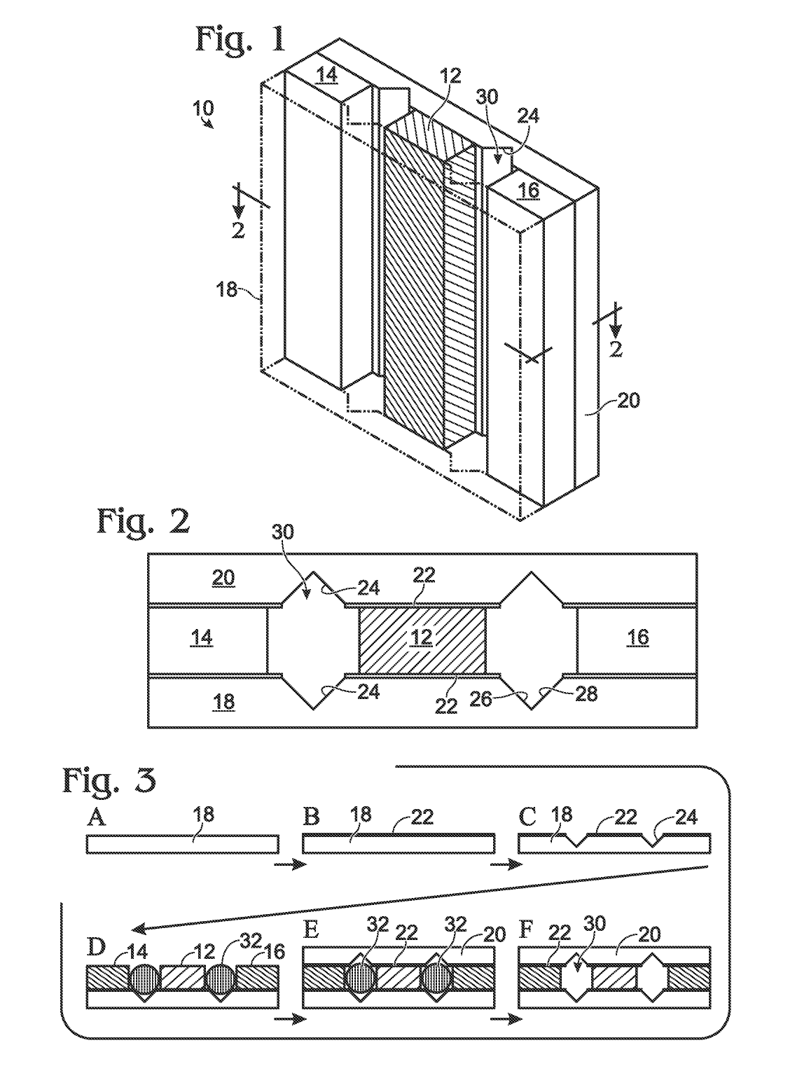

This example describes an exemplary pump diode assembly 10 having at least one emitter, in accordance with aspects of the present disclosure; see FIGS. 1 and 2. The pictured embodiment includes one emitter and two spacers. However, in other embodiments, one or both spacers may be replaced by additional emitters to increase the fill factor of the diode assembly. Yet other embodiments may include larger numbers of emitters and/or spacers (see, for example, Examples 3 and 5).

FIGS. 1 and 2 show diode assembly 10 in isometric and cross-sectional views, respectively. Diode assembly 10 includes one emitter 12, two spacers 14, 16, and first and second substrates 18, 20, configured such that the emitter and spacers are sandwiched between, and at least partially supported by, the first and second substrates. Conductive layers 22 (visible in FIG. 2) may be disposed adjacent the first and second substrates (in particular, between each substrate and the emitter and, optionally, the spacers). The conductive layers may facilitate electrical contact with the emitter, allowing it to be powered. The conductive layers may be a coating, such as an electrical conductive metal plating, on surfaces of the substrates, especially at least on surfaces of the substrates that are in contact with the emitter and, optionally, the spacers. Additionally and/or alternatively, the surfaces of the substrates, emitter(s) and/or spacer(s) may include a conductive layer, or other conductive element, such as a continuous strip of conductive material and/or discrete conductive areas. First and/or second substrates, 18, 20, which also may be referred to as anode and cathode, may symmetrically clamp emitter 12 and may provide equal two-sided heat removal and/or electrical isolation. This same mechanism also may be used for linear and/or two-dimensional X/Y multiplexing emitter arrays, for example, as described below.

First and/or second substrate 18, 20 may include or define at least one groove 24, or a plurality of grooves, also referred to as laser grooves or divots, which may be formed through conductive layer 22 and, optionally, partially into the substrate. Grooves 24 may be formed in first and/or second substrate 18, 20 before, during, or after application of plating layer 22 and may provide electrical isolation between elements (e.g., emitters and/or between emitters and spacers) of the pump diode assembly. Grooves 24 may, independently of one another, have any suitable or appropriate shapes and dimensions. For example, the grooves may have a width that is smaller than the width of emitter 12 to increase the fill factor of the pump diode assembly. In the pictured embodiment, each groove 24 may be defined by a first wall 26 and a second wall 28, the first wall and second wall being nonparallel and converging with a roughly triangular cross-section to the bottom of each groove 24. In other embodiments, the grooves may have a semi-circular or square cross-section, among others. The particular shape may reflect the use(s) to which the grooves are put and/or the method(s) by which the grooves are produced.

The plurality of grooves 24 of the first and second substrate 18, 20 may align such that when the substrates are apposed and mated, as shown in FIG. 1, a plurality of long semi-circular guide holes 30 is formed. Guide holes 30 and/or grooves 24 may remain empty and/or be filled with a suitable filler material (e.g., fiber-like, insulating, non metallic, and/or adhesive filler material, among others). The removable or non-removable filler material may guide, hold, and/or space the elements (emitters, spacers) and/or substrates apart, aid in emitter and/or substrate alignment, and/or limit solder flow/stacking. The filler material may include insulating, round, fiber-like guides having a length and a diameter configured to fit at least partially within the grooves.

Emitter 12 may be disposed between two of the plurality of grooves 24. One or more isolating spacers 14, 16 may be disposed adjacent emitter 12 such that at least one groove 24 separates spacers 14, 16 and emitter 12. In alternative embodiments, one or both of spacers 14, 16 may be replaced by a second or third emitter to increase the fill factor of pump diode assembly 10. In some embodiments, there may be more spacers than emitters, such that the element at each end (in symmetric embodiments) or at one end (in asymmetric embodiments) of the element array is a spacer. In other embodiments, there may be fewer spacers than emitters, such that the element at each end (in symmetric embodiments) or at one end (in asymmetric embodiments) of the element array is an emitter. Depending on the application, embodiments may include relatively more emitters to increase light production or relatively more spacers to facilitate cooling.

Emitter 12 and spacers 14, 16 may be disposed between grooves 24 in a substantially parallel pattern. Thus, the shapes and dimensions of emitter 12 and spacers 14, 16 and the surface area of substrate 18, 20 between grooves 24 may be related. The surface area of substrate 18, 20 between grooves 24 may be at least substantially planar, for example, as depicted in FIGS. 1 and 2. When the surface area of substrate 18, 20 between grooves 24 is substantially planar, the elements (emitters 12 and spacers 14, 6) may be elongate and flat on at least one side, to be placed on the planar surface area of substrate 18, 20 between grooves 24.

First and/or second substrate 18, 20 also may include other structures, such as substrate clamps, channels, and/or indentations, among others, for any suitable purpose(s). The substrate clamps may hold or support portions of the pump diode assembly, in relation to one another and/or to components of a larger system in which the pump diode assembly is employed. The channels and/or indentations may facilitate supplying power to the emitters, for example, by providing space for receiving wires, such as power supply bus wires. Alternatively, or in addition, the channels and/or indentations may facilitate cooling the emitters, for example, by forming channels for conducting coolant (although some embodiments, such as the pictured embodiment, may be air cooled).

Spacers 14, 16 may, in some embodiments, be formed integral with one or both of substrates 18, 20. For example, spacers 14, 16 and substrate 20 could be a unitary structure, with the emitter sandwiched between a planar substrate (18) and a U-shaped unitary substrate/spacer (14+16+20). Alternatively, spacer 14 and substrate 18 could be unitary, and spacer 16 and substrate 20 could be unitary, with the emitter sandwiched between two anti-parallel L-shaped unitary substrate/spacers (14+18 and 16+20). Finally, one substrate could be planar and one substrate/spacer could be L-shaped, with the emitter and remaining spacer sandwiched in between.

### Example 2

### Method of Manufacturing a Pump Diode Assembly

This example describes an exemplary method for manufacturing a pump diode assembly, such as the pump diode assembly of FIG. 1, in accordance with aspects of the present disclosure; see FIG. 3.

FIG. 3 shows an exemplary series of configurations (Panels A-F) produced during manufacture of the pump emitter assembly of FIG. 1. For clarity, and to emphasize the emitter, substrates and spacers are shown without hatching.

Panel A. A substrate 18 is obtained.

Panel B. A conductive layer 22 is applied to a surface of substrate 18, using any suitable method. For example, the conductive layer may be applied using chemical vapor deposition (CVD), among others. The surface(s) receiving the conductive layer may include, or be limited to, surfaces that will contact emitters and/or spacers.

Panel C. A plurality of grooves 24 is formed through conductive layer 22 and, optionally, partially through first substrate 18, using any suitable method. For example, the grooves may be formed by etching, such as laser etching, among others.

Panel D. Removable or non-removable, insulating, round, fiber-like guide filler(s) 32 may be aligned within grooves 24 to aid in accurate spacing of the elements (emitter 12 and/or spacer(s) 14, 16) and maintenance of accurate emission direction of emitter 12. Emitter 12 is positioned or deposited on conductive layer 22 between two of plurality of grooves 24. Additional elements, such as additional emitters and/or spacer(s) 14, 16, are positioned adjacent emitter 12, such that at least one groove 24 separates the elements, here spacers 14, 16, from emitter 12. More generally, any suitable mechanism(s) may be used for aligned and positioning emitters and/or spacers.

Panel E. Second substrate 20 having conductive layer 22 may be deposited on top of emitter 12 and spacers 14, 16. The second substrate may have a similar configuration as the first substrate and may be aligned with the first substrate. The second substrate may be produced as described above, for Panels A-C, among others.

Panel F. Guide filler 32 may be removed. Guide holes 30 provide insulating space between emitter 12 and spacers 14, 16.

The steps described above may be performed in any suitable order, any suitable number of times. In some embodiments, one or both of spacers 14, 16 may be replaced with a second and/or a third emitter to increase the fill density of the pump diode assembly or module. In some embodiments, the conductive layer may be applied to the emitter(s) and/or spacer(s), instead of or in addition to the substrates. In some embodiments, guide filler(s) may not be removed.

### Example 3

### Pump Diode Assemblies with a Linear One-Dimensional Array

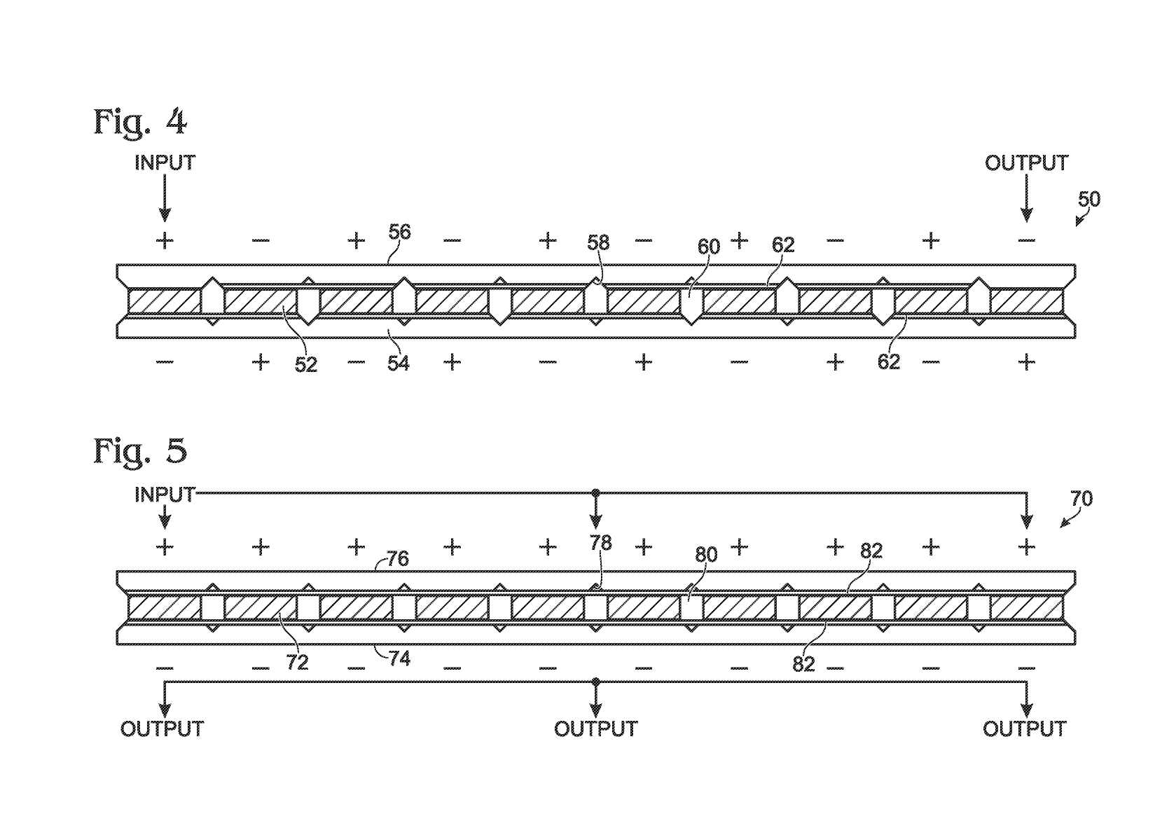

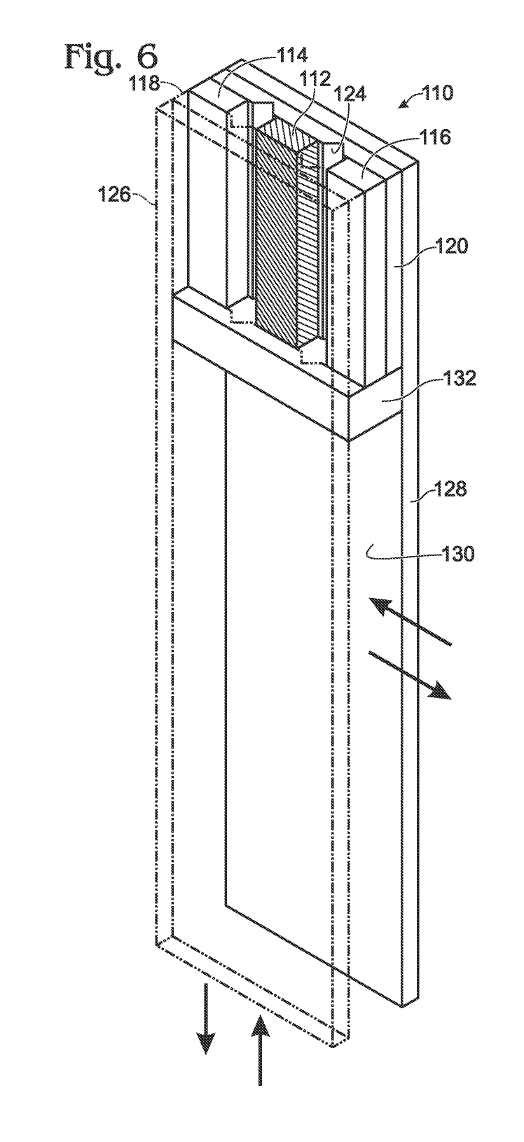

This example describes exemplary pump diode assemblies having linear one-dimensional arrays of N emitters, in accordance with aspects of the present disclosure; see FIGS. 4 and 5. The number N of emitters may be selected according to any suitable criteria, such as intended use. Exemplary numbers may include 2, 3, 5, 10 (as shown), 15, 20, or more, among others. Power may be supplied to the emitters using any suitable mechanism(s), including series (e.g., FIG. 4), parallel (e.g., FIG. 5), and/or a combination thereof (e.g., parallel across adjacent pairs of emitters and in series across adjacent pairs of pairs of emitters, among others).

Series Embodiment

FIG. 4 shows a cross-sectional view of a linear pump diode assembly 50 of ten (10) single emitters, or emitters, connected in series, in accordance with aspects of the present disclosure.

Pump diode assembly 50 includes a plurality of emitters 52 between a first and second substrate 54, 56. Pump diode assembly 50 may be at least substantially as described above, for example, in Example 1. Namely, a plurality of grooves 58 may be interspersed among emitters 52 such that emitters 52 may be separated by grooves 58.

Emitters 52 and grooves 58 may define a plurality of guide holes 60 that may be filled with an insulating filler material.

Conductive layers 62 may be disposed adjacent the first and second substrates 54, 56. In this “series” embodiment, conductive layer 62 may span across grooves 58 in an alternating pattern such that an electrical current, indicated by directional arrows identified as “INPUT” and “OUTPUT,” may run along the length of diode array 50 by flowing back and forth across the assembly, in opposite directions through adjacent emitters. Voltages and currents used to power the diode array may depend on particulars of the individual emitters, the number of emitters, the desired light output, and so on. An exemplary series input may be approximately 20 Volts (V) and 20 Amps (A). All other things being equal, in the series mounting arrangement, exemplary operating current may be reduced from parallel operating current, described below with reference to FIG. 5.

Parallel Embodiment

FIG. 5 shows a cross-sectional view of a linear pump diode assembly 70 of ten (10) single emitters, or emitters, connected in parallel, in accordance with aspects of the present disclosure. Here, emitters 72, substrates 74, 76, plurality of grooves 78, and guide holes 80 may be at least substantially as described above, for the series configuration. Conductive layers 82 may similarly be disposed adjacent the first and second substrates 74, 76. However, in this “parallel” embodiment, conductive layer 82 is configured such that the emitters are connected in parallel. Specifically, conductive layer 82 may span the width of grooves 78 such that an electrical current, indicated by directional arrows identified as “INPUT” and “OUTPUT,” may run across pump diode assembly 70, with one side of each emitter at one potential, and the other side of each emitter at another potential. Voltages and currents used to power the diode array may again depend on particulars of the individual emitters, the number of emitters, the desired light output, and so on. For example, an exemplary parallel input may be approximately 2 Volts (V) and 200 Amps (A).

Pump diode assemblies 50, 70 also may include other structures, such as substrate clamps, channels, and/or indentations, for any suitable purpose(s), at least substantially as described above, for example, in Example 1. The pump diode assemblies further may include spacers replacing one or more of the emitters, again as described above.

### Example 4

### Pump Diode Assembly Including a Cooling Channel

This example describes an exemplary pump diode assembly, shown in association with a cooling fluid channel, in accordance with aspects of the present disclosure; see FIG. 6.

FIG. 6 shows an isometric view of a pump diode assembly 110. The construction of pump diode assembly 110 may be substantially similar to the embodiment described in Example 1. Namely, pump diode assembly 110 may include a plurality of elements, including an emitter 112 and/or a spacer(s) 114, 116, a first substrate 118 and a second substrate 120, configured such that the emitter and spacers are sandwiched between, and at least partially supported by, first and second substrates 118, 120. Conductive layers may be disposed adjacent the first and second substrates (in particular, between each substrate and the emitter and, optionally, the spacers). First and/or second substrate 118, 120 may include or define a plurality of grooves 124, also referred to as laser grooves or divots, which may be formed through the conductive layer and, optionally, partially into the substrate. Grooves 124 and the elements (diode(s), spacer(s)) may form a guide hole that, optionally, may be filled with a suitable filler material.

Pump diode assembly 110 may further include one or more extended cooling blades 126, 128, which may alternatively be described as extended substrates. Cooling blades 126, 128 may form a channel 130 through which dry or wet cooling fluid may flow or be directed, in accordance with aspects of the present disclosure, as indicated by the directional arrows, thereby reducing or eliminating the need of the pump diode assembly for microchannel coolers.

Cooling blades 126, 128 may comprise separate substrates, mounted adjacent first and/or second substrates 118, 120, as shown in FIG. 6. Alternatively, or in addition, the cooling blades may simply comprise extended versions of the first and/or second substrates of FIGS. 1 and 2. In either case, cooling blades 126, 128 may be longer than emitter(s) 112 and/or spacer(s) 114, 116 such that cooling blades 126, 128 extend beyond a sealing block 132 disposed at the end of emitter 112, spacers 114, 116 and/or first and second substrates 118, 120. The extended substrate length, extending beyond the emitter and/or other elements, may aid in dissipating heat generated by the pump diode assembly by conducting heat away from the diode(s). Furthermore, cooling blades 126, 128 may be cooled by fluid such as air or water, dissipating additional heat and generally improving the temperature stability of pump diode system 110.

Pump diode assembly 110, like other embodiments described herein, may have any suitable dimensions. For example, the approximate dimensions of an exemplary assembly may be about 0.50 mm total thickness, about 0.90 mm total width, and about 3.60 mm total length. In this exemplary embodiment, the length of cooling blades 126, 128 extending beyond sealing block 132 may be about 2.40 mm.

The disclosed pump diode assembly 110 may be extended and/or multiplied to include multiple diode(s), spacer(s) adjacent one another (forming a one-dimensional array) and/or multiple diode(s), spacer(s) and/or substrate(s)stacked on top of one another (forming a two-dimensional array). An exemplary embodiment of such a two-dimensional configuration is described in further detail in Example 5.

### Example 5

### Pump Diode Assembly with Two-Dimensional Array

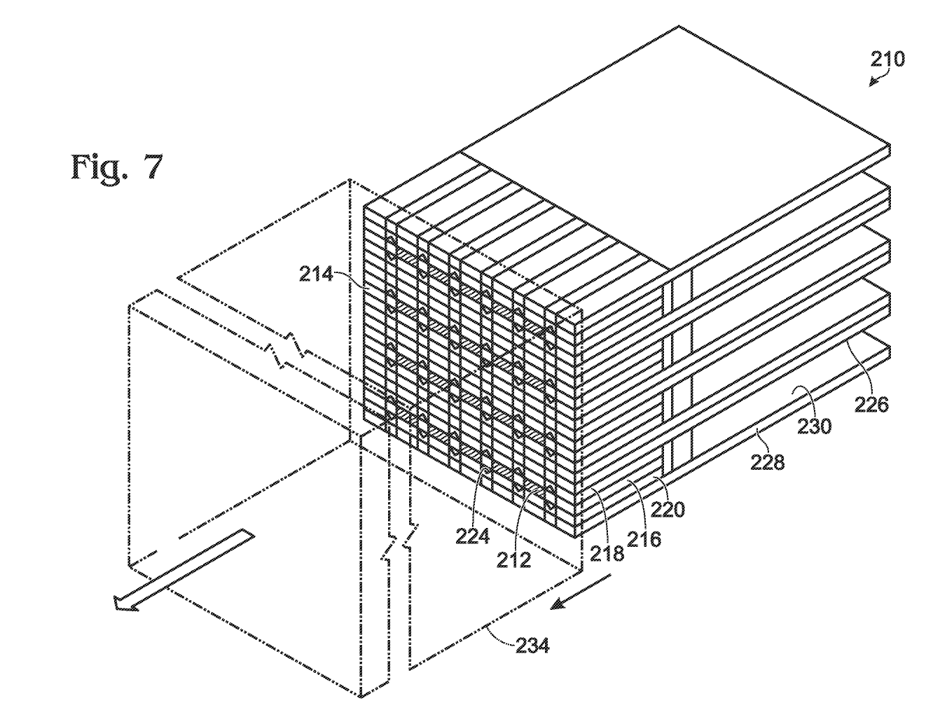

This example describes a pump diode system including a two-dimensional array of emitters, shown in association with a plurality of water channels and interfaced with a suitable gain medium, in accordance with aspects of the present disclosure; see FIG. 7. Multi-emitter X/Y arrays may produce up to ten times (10 X) higher output energy/power from the same volume, for example, with up to 80% fill factor. Additionally, as shown in FIG. 7, the X/Y array may pump a water cooled lasing/gain medium slab.

FIG. 7 shows an isometric view of a pump diode assembly 210 including a two-dimensional array of emitters. The construction of pump diode assembly 210 may be substantially similar to the embodiments described in Examples 1 and 4. Namely, pump diode assembly 210 may include a plurality of elements, including an emitter 212 and/or spacers 214, 216, a first substrate 218 and a second substrate 120, configured such that the emitter and spacers are sandwiched between, and at least partially supported by, the first and second substrates. Conductive layer(s) may be disposed adjacent the first and second substrates (in particular, between each substrate and the emitter and, optionally, the spacers). First and/or second substrate 218, 220 may include or define a plurality of grooves 224, which may be formed through the conductive layer and, optionally, partially into the substrate. Grooves 224 and the elements (diode(s), spacer(s)) may form a guide hole that, optionally, may be filled with a suitable filler material.

Pump diode assembly 210 may further include one or more extended cooling blades 226, 228, which may alternatively be described as extended substrates. Cooling blades 226, 228 may form a channel 230 through which dry or wet cooling fluid may flow or be directed, in accordance with aspects of the present disclosure. Cooling blades 226, 228 may comprise separate substrates, mounted adjacent first and/or second substrates 218, 220, as shown in FIG. 6. Alternatively, or in addition, the cooling blades may simply comprise extended versions of first and/or second substrates 218, 220 of FIGS. 1 and 2. In either case, the cooling blades may be longer than emitter(s) 212 and/or spacer(s) 214, 216 such that cooling blades 226, 228 extend beyond a sealing block 232 disposed at the end of emitter 212, spacers 214, 216 and/or first and second substrates 218, 220. In the embodiment shown, substrate cooling blades 226, 228 form four (4) cooling channels 230 and provide ten cooling interface surfaces for direct, indirect, dry or wet cooling.

Emitter(s) 212 may be disposed adjacent a lasing medium, such as a lasing medium slab 234, such that emitter 212 pump beam direction, indicated by the small black arrow, is directed towards lasing medium slab 234. Lasing medium slab 234 may be constructed from any material(s) capable of lasing, for example, a material such as a suitable rod, slab, and/or crystal (referred to herein as, but not limited to, a “slab”) capable of creating a population inversion within the slab. Exemplary lasing medium materials include yttrium aluminum garnet doped with neodymium ions (Nd:YAG), ruby (or chromium doped sapphire), neodymium doped glass, neodymium doped vanadate, and/or alexandrite, among others. Generally, any material having atoms with at least three, and preferably at least four, energy levels may be suitable, so long as one of the intermediate energy levels decays relatively slowly as compared to the other decay processes. In the embodiment shown, lasing medium slab 234 includes four cooling interface surfaces for direct, indirect, dry or wet cooling. The lasing medium output is shown by the large arrow directed out of the lasing medium slab 234. Pump diode assembly 210 may be provided with or without a lasing medium slab. In the latter case (at least), the pump diode assembly may be configured to be attached to or otherwise integrated with a separate lasing medium.

In some embodiments, currently available emitters may be used. The emitters may have sizes and/or optical outputs as identified below:

Emitters (500μ wide, 100μ thick, 1 mm cavity length) may be used to form approximately 1.6 mm×1.6 mm (X/Y active area) array having 20 emitters (4×5). Each emitter may have an optical output of approximately 2 watts (W) in Continuous Wave (CW) mode or approximately 20 W peak in Quasi-CW (QCW) mode of pulsed operation. The 1.6 mm×1.6 mm emission (or active) area X/Y 4×5 array may produce total optical output of 40 W CW or 400 W peak QCW in their respective modes of operation.

This X/Y array proper gain absorption matched output wavelength diode output will be directly coupled to the gain medium of proper size and length, for example, 2.5 mm×2.5 mm×12 mm gain absorption length. The total area for the pump diode assembly having X/Y (4×5) array as described above and including substrate blades may be 2.05 mm×2.30 mm×3.41 mm length.

Alternatively, emitters 200μ wide, 100μ thick, 2 mm cavity (approximately 8 W CW and 80 W peak QCW each) may be used for the same X/Y (4×5) array and the total array will produce 160 W CW or 1600 W peak QCW respectively. Similarly, emitters 200μ wide, 100μ thick, 3 mm cavity (approximately 10 W CW and 100 W peak QCW each) may be used for the same X/Y (4×5) array, approximately at least 200 W CW or 2000 W peak QCW will be produced respectively.

### Example 6

### Pump Diode Assembly Multiplexing

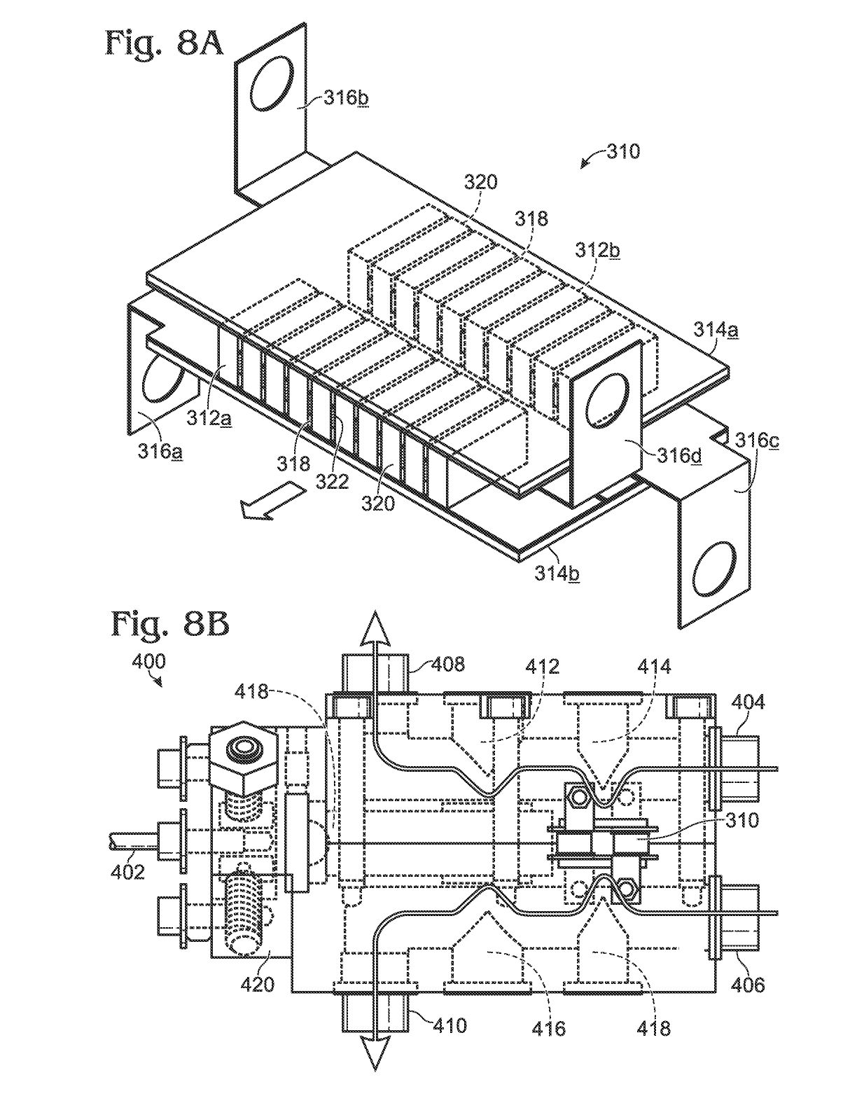

This example describes an embodiment of pump diode assembly multiplexing, with emphasis on dual-sided cooling of a high brightness diode array (HBDA) module, in accordance with aspects of the present disclosure; see FIG. 8AB.

FIG. 8A shows an isometric view of a multiplexed pump diode assembly 310. The assembly includes two electrically isolated HBDA modules 312a,b, each comprising a plurality of emitters/diode bars, mounted (e.g., sandwiched or clamped) back-to-back between top and bottom substrates or cooling plates 314a,b. The cooling plates may allow two-sided (e.g., top and bottom) cooling access to the HBDA modules. The cooling plates may be coupled to electrodes 316a-d that may be used to supply electrical power to the HBDA modules. In the pictured embodiment, the HBDA modules are elongate structures having long axes that are at least substantially parallel to one another and at least substantially perpendicular to the optical axes of the associated emitters. The electrodes are mounted at opposite ends of the HBDA modules, two on each cooling plate. The electrodes may, more generally, be mounted at any suitable location(s) or be omitted altogether (particularly in embodiments in which power is supplied directly to the HBDA modules). The cooling plates further may include a contact layer that may extend beyond the substrate.

HBDA modules 312a,b, in turn, each include an array of emitters/diode bars 318 and spacers 320. For example, each HBDA module in the pictured embodiment includes nine single emitter formed diode bars 318 and ten spacers 320. The diode bars are separated from one another, and bracketed at each end of the HBDA module, by the spacers. The HBDA modules may, more generally, include any suitable or desired number of emitters/diode bars, for example, one, two, three, four, five, nine, or ten, among others, arranged in any suitable configuration. The diode bars may include a single emitter 322, as shown in FIG. 1. Alternatively, some or all of the diode bars may include additional emitters (e.g., replacing spacers shown in FIG. 1). The diode bars may be connected in series or parallel configurations, among others, with series configurations potentially requiring a much reduced current for operation.

The disclosed configuration may provide improved thermal management, especially in situations in which the pump diode assemblies include emitter(s) having longer than conventional cavities. Currently, cavity lengths range from 1 mm to 4 mm with continuous wave (CW) power scaling from 2 to 10 watts, respectively. The pump diode assembly multiplexing of FIG. 8A, having nine pump diode assemblies forming a high brightness series connected module, may efficiently couple into a 100 micron diameter optical fiber. Additionally and/or alternatively, a smaller number of pump diode assemblies and/or emitters may couple into smaller diameter fiber. For example, a pump diode assembly multiplex having four pump diode assemblies, each having a single emitter, may couple into a 50 micron diameter fiber.

Exemplary sizes, electrical inputs, optical outputs, and other pertinent parameters are described below, by way of example.

The two large substrates sandwiching the two sets of nine pump diode assemblies may have the approximate size of L=16 mm×W=9 mm. Each pump diode assembly may be 150 μm thick×750 μm wide×3 mm long cavity and facet size of 1 μm×500 μm. The spacers may be approximately 1 mm×2 mm.

The nine pump diode assemblies in each HBDA module each may be operated at 1.8 V for a total of (9×1.8V=16.2 volts) and a much reduced current, such as 15 amps for CW operation (243 W electrical input) or 50 amps for quasi-CW (QCW) with 50% duty cycle operation, generating 405 W of electrical or thermal loading. If both HBDA modules are operated, the system thermal loading can be doubled. A power supply having the CW and QCW diode driver capability of up to 1200 watts at 10-48 volts may be provided for operation. Accordingly, both HBDA modules can be driven simultaneously in series or in CW mode 486 Watts (32.4 volts at 15 amps) or QCW with 50% duty cycle 810 Watts (32.4 volts at 25 amps) will be provided by power supply.

FIG. 8B shows a side view of an exemplary HBDA system 400, including the pump diode assembly multiplex of FIG. 8A, coupled to a lasing medium fiber and cooling system. Specifically, in the pictured embodiment, the output of multiplexed pump diode assembly 310 may be coupled into a 100 micron diameter 0.22 Numerical Aperture (NA) fiber 402. Fiber 402 may be adjustable along the Z-axis. Cooling fluid inputs 404, 406 and cooling fluid outputs 408, 410 may direct cooling fluid, such as air or water, past and/or through multiplexed pump diode assembly 310. HBDA system 400 may further include top flow directors 412, 414 and bottom flow directors 416, 418. HBDA system 400 may provide VGB space 418, an emitter imaging lens 422, and a fiber imaging lens assembly 420. Fiber imaging lens assembly 420 may be X-Y adjustable. The total weight of HBDA system may be less than 45 grams. More generally, pump diode assemblies in accordance with the present disclosure may be coupled to other fibers, or additional fibers, or deliver light directly, among others. They also may be cooled using any suitable mechanism(s).

Coupling a pump diode assembly to a fiber may be cost effective. Additionally and/or alternatively, such coupling may provide higher output from the fiber, which may increase the power of communication fibers, thereby requiring fewer junctions, less distance to be traveled, and/or more data. Additionally, compact high power/energy industrial and/or directed energy laser weapons can be manufactured from pump fiber laser by creating higher output from a small diameter fiber(s).

### Example 7

### Exemplary Applications

This example describes exemplary applications of the various systems described herein, including but not limited to the pump diode assemblies, pump head assemblies, diode pumped laser systems, and components and combinations thereof. These systems could have significant government and commercial applications, with uses in the military, law enforcement, environmental assessment, medicine, and industry, among others.

The military/law enforcement/environmental applications include transportable-pier-mounted and helicopter-mounted mass-surveillance of the domestic shallow shoreline environment. The Environmental Protection Agency (EPA) has expressed a need to monitor underwater costal deposits to catch the unseemly, criminal activities of dumping hazardous waste off the shore of the United States. The EPA as well as state and local governments have a pressing need to map the shallow deposits (with time stamps and GPS stamps) of coastal shorelines (say to four meters depth). This includes both freshwater lakes and ocean beaches and piers. Local police authorities are interested in such maps to identify dumped contraband and corpses. These maps are critical to criminal prosecution of illegal dumping and cuing law enforcement to potential evidence areas.

The military/law enforcement applications also include scanning underwater surveillance systems, underwater guidance and communication systems, and light detection and ranging (LIDAR). The blue-green portion of the spectrum is particularly suited for these applications due to the optical windows that exist in this region. Present systems, if they exist for all these applications, are cumbersome and inefficient. A high-power, highly efficient solid-state laser system capable of operating in the blue-green or other wavelength regions such as eye-safe regions opens the possibilities for incorporating these technologies into many other important military application areas. High-power laser systems also will open the potential for tunability and multi-colored operation, which would allow secure communications by selecting the wavelength that was attenuated by the medium the most, but still provide adequate message capability. The ability to frequency hop, similar to radio, also makes this an even more secure line-of-sight communication technique. With this technology, applications such as laser-based friendly or foe identification systems can become a near-future reality. The development of this solid-state laser will allow the government the opportunity to investigate these and many other applications such as laser-induced spectroscopy for remote sensing, among others.

Other non-limiting military applications may include military gimbal systems for aircraft and other vehicles, military directed energy lasers, range finders, designators, and/or illuminators.

The medical applications include use of this high-power, diode-pumped, Q-switched 1064 nm laser as a pump source to generate other wavelengths by means of solid-state crystal converters. Applications include Photo Dynamic Therapy (PDT) in the areas of dermatology, ophthalmology, and/or general surgery. All tissues have characteristic absorption spectra. If the proper part of the spectrum is selected, particular tissues can be treated, while other surrounding tissues remain unaffected. By selecting the wavelength, less power would be required for treatment with less likelihood of damage to adjacent healthy tissue. Currently, medical lasers have limited tunability or none at all, have poor efficiencies, and are large and cumbersome in design. The tunable, highly efficient solid-state design of some of the disclosed embodiments with air-cooling would partially or completely overcome the current limitations. Additional nonlimiting examples include compact multi wavelength laser systems and/or laser razor (hair removal/shaving) home kit systems.

The industrial applications include cutting and welding. The material would have to be selected for the amount of energy required and the absorption characteristics of the material. A tunable high-power solid-state laser could be used on some of the plastic and composite materials that currently are very difficult to process, such as the boron fiber composite. Currently, there are plastic/composite materials being processed by using metal cutting lasers, but most of these lasers are much larger than necessary, inefficient, and not entirely suited for the job. Additional non-limiting industrial applications include telecommunication fiber coupled laser modules.

Industrial laser pump manufacturing and application examples include but are not limited to scribing lasers for future electrical power generation using solar panels, uranium enrichment/isotope separation (very high energy, high beam quality, short pulse, high peak energy/power, non-linear wavelength conversion) laser systems, and/or multi wavelength, single emitter stable RGB lasers for a LASER TV product.

### Example 8

### Selected System Embodiments

This example describes additional aspects of exemplary pump diode assemblies, in accordance with aspects of the present disclosure, presented without limitation as a series of numbered paragraphs.

1. A pump diode assembly for a diode pumped laser, comprising: (A) a first substrate; (B) a second substrate; and (C) an emitter disposed between the first substrate and the second substrate; wherein the first substrate includes a first plurality grooves and the emitter is positioned between two of the first plurality of grooves.

2. The pump diode assembly of paragraph 1, wherein the second substrate includes a second plurality of grooves that aligns with the first plurality of grooves of the first substrate.

3. The pump diode assembly of paragraph 1, further comprising a second emitter disposed between the first substrate and the second substrate, the emitters being separated from one another by at least one of the first plurality of grooves.

4. The pump diode assembly of paragraph 1, wherein the at least one of the first plurality of grooves includes a guide filler.

5. The pump diode assembly of paragraph 1, further comprising a thermally conductive spacer disposed between the first substrate and the second substrate and separated from the emitter by at least one of the first plurality of grooves.

6. The pump diode assembly of paragraph 5, wherein the at least one of the first plurality of grooves includes a guide filler.

7. The pump diode assembly of paragraph 1, wherein the first substrate has a length greater than that of the emitter and the first substrate is configured to direct heat away from the emitter.

8. The pump diode assembly of paragraph 7, wherein the first substrate is configured to be cooled by a liquid.

9. The pump diode assembly of paragraph 7, wherein the first substrate is configured to be cooled by a gas.

10. The pump diode assembly of paragraph 1, further comprising a conductive layer disposed between the first substrate and the emitter.

11. The pump diode assembly of paragraph 1, wherein each of the first plurality of grooves is defined by a first wall and a second wall, the first wall and second wall being nonparallel and converging to the bottom of each groove.

12. The pump diode assembly of paragraph 1, wherein the width of the grooves in the first plurality of grooves is smaller than the width of the emitter.

13. The pump diode assembly of paragraph 1, wherein each of the first plurality of grooves is defined by a first wall and a second wall, the first wall inclined in relation to a major surface of the substrate and intersects the bottom of the groove at an angle.

14. The pump diode assembly of paragraph 1, wherein the first plurality of grooves are in parallel adjacent rows.

15. The pump diode assembly of paragraph 10, wherein the conductive layer includes metal plating.

16. A pump diode assembly for a diode pumped laser, comprising: (A) a plurality of emitters, each of the plurality of emitters having a top side and a bottom side; (B) a first substrate configured to conduct heat away from the emitters, the first substrate including a plurality of substantially planar surfaces in contact with the top side of the emitters, the planar surfaces separated by a first plurality of grooves in the first substrate; and (C) a second substrate configured to conduct heat away from the emitters, the second substrate in contact with the bottom side of the emitters.

17. The pump diode assembly of paragraph 16, wherein the second substrate includes a plurality of substantially planar surfaces in contact with the bottom side of the emitters, the planar surfaces separated by grooves that align with the grooves in the first substrate.

18. The pump diode assembly of paragraph 17, further comprising an electrically conductive element disposed between wherein each of the plurality of substantially planar surfaces is coated with an electrically conductive layer in contact with the top side of the emitters.

19. A method of manufacturing a pump diode assembly for a diode pumped laser, comprising: (A) depositing an conductive layer on a first substrate; (B) forming a first plurality of grooves through the conductive layer and partially through the first substrate; (C) placing a emitter on the conductive layer between two of the first plurality of grooves; and (D) placing a second substrate on the emitter such that the emitter is disposed between the first and second substrates.

20. The method of paragraph 19, further comprising: depositing a conductive layer on the second substrate; and forming a second plurality of grooves, complementary to the first plurality of grooves, partially through the second substrate; wherein placing the second substrate on the emitter further comprises aligning the second plurality of grooves with the first plurality of grooves.

21. The method of paragraph 19, further comprising placing a second emitter on the first conductive layer such that at least one of the first plurality of grooves is between and separates each emitter.

22. The method of paragraph 19, further comprising at least partially filling a groove with a guide filler.

23. The method of paragraph 21, wherein the conductive layers are configured so that an electrical current will flow through each emitter in series.

24. The method of paragraph 21, wherein the conductive layers are configured so that an electrical current will flow through each emitter in parallel.

25. The method of paragraph 19, further comprising placing a thermally conductive spacer on the conductive layer such that at least one of the first plurality of grooves is between the emitter and the thermally conductive spacer.

26. The method of paragraph 25, further comprising filling the area between the emitter and the thermally conductive spacer with a guide filler.

27. A pump diode assembly for a diode pumped laser, comprising: (A) a substrate; (B) a conductive layer disposed on the substrate; and (C) a emitter disposed on the conductive layer; wherein a plurality of grooves are formed through the conductive layer and partially into the first substrate; and wherein the diode is positioned between two of the plurality of grooves.

28. The pump diode assembly of paragraph 27, further comprising a second emitter disposed on the conductive layer such that each emitter is separated from the other by at least one of the plurality of grooves.

29. The pump diode assembly of paragraph 27, further comprising a spacer disposed on the conductive layer such that the emitter and the spacer are separated by at least one of the plurality of grooves.

30. The pump diode assembly of paragraph 27, wherein each of the first plurality of grooves is defined by a first wall and a second wall, the first wall and second wall being nonparallel and converging to the bottom of each groove.

31. The pump diode assembly of paragraph 27, wherein each groove in the plurality of grooves has a width that is smaller than that of a width of the emitter.

32. The pump diode assembly of paragraph 27, wherein each of the first plurality of grooves is defined by a first wall and a second wall, the first wall inclined in relation to a major surface of the substrate and intersects the bottom of the groove at an angle.

33. The pump diode assembly of paragraph 27, wherein the plurality of grooves are in parallel adjacent rows.

34. The pump diode assembly of paragraph 27, wherein the length of the first substrate extends beyond the emitter along the illumination axis of the diode bar.

35. A multiplexed pump diode assembly for a diode pumped laser comprising; (A) a first substrate; (B) a second substrate; and (C) a first diode array module including a plurality of diode bars having at least one emitter, the diode array having a long axis that is at least substantially perpendicular to the optical axes of the emitters; wherein the first diode array module is disposed between the first substrate and the second substrate.

36. The multiplexed pump diode assembly of paragraph 35, wherein the plurality of diode bars are electrically connected to one another in series.

37. The multiplexed pump diode assembly of paragraph 35, wherein the first and second substrates are coupled to a first electrode and a second electrode configured to supply electrical power to the first diode array module.

38. The multiplexed pump diode assembly of paragraph 35, further comprising a second diode array module between the first and second substrates, the second diode array module being eclectically isolated from the first diode array module and including a plurality of diode bars having at least one emitter.

39. The multiplexed pump diode assembly of paragraph 38, wherein the optical axes of the emitters of the first diode array and the optical axes of the second diode array are parallel and project in opposite directions.

40. The multiplexed pump diode assembly of paragraph 35, further comprising an electrically conductive contact layer between the first substrate and the first diode array.

41. The multiplexed pump diode assembly of paragraph 35, wherein at least one of the diode bars includes a pump diode assembly comprising: (A) a first substrate; (B) a second substrate; and (C) an emitter disposed between the first substrate and the second substrate; wherein the first substrate includes a first plurality grooves and the emitter is positioned between two of the first plurality of grooves.

42. The multiplexed pump diode assembly of paragraph 35, wherein the first substrate and the second substrate are cooled by one of gas and water.

43. The multiplexed pump diode assembly of paragraph 35, further comprising a pump laser fiber.

The systems disclosed herein may be combined, optionally, with apparatus, methods, compositions, and/or kits, or components thereof, described in the references incorporated herein by reference, particularly U.S. Pat. No. 7,529,286 to Gokay et al.

The disclosure set forth herein may encompass multiple distinct inventions with independent utility. The disclosure includes a number of section headings, which were added for convenience, and which are not intended to limit the disclosure in any way (e.g., the headings to not foreclose using information described in one section in place of, and/or in combination with, information described in other sections). Similarly, the disclosure relates information regarding specific embodiments, which are included for illustrative purposes, and which are not to be considered in a limiting sense, because numerous variations are possible. The inventive subject matter of the disclosure includes all novel and nonobvious combinations and subcombinations of the various elements, features, functions, and/or properties disclosed herein. The following claims particularly point out certain combinations and subcombinations regarded as novel and nonobvious. Inventions embodied in other combinations and subcombinations of features, functions, elements, and/or properties may be claimed in applications claiming priority from this or a related application. Such claims, whether directed to a different invention or to the same invention, and whether broader, narrower, equal, or different in scope to the original claims, also are regarded as included within the subject matter of the inventions of the present disclosure.

What is claimed is:

1. A pump diode assembly for a diode pumped laser, comprising:
a first substrate;
a second substrate; and
an emitter disposed between the first substrate and the second substrate;
wherein the first substrate includes a first plurality grooves and the emitter is positioned between two of the first plurality of grooves.

2. The pump diode assembly of claim 1, wherein the second substrate includes a second plurality of grooves that aligns with the first plurality of grooves of the first substrate.

3. The pump diode assembly of claim 1, further comprising a second emitter disposed between the first substrate and the second substrate, the emitters being separated from one another by at least one of the first plurality of grooves.

4. The pump diode assembly of claim 1, wherein the at least one of the first plurality of grooves includes a guide filler.

5. The pump diode assembly of claim 1, further comprising a thermally conductive spacer disposed between the first substrate and the second substrate and separated from the emitter by at least one of the first plurality of grooves.

6. The pump diode assembly of claim 5, wherein the at least one of the first plurality of grooves includes a guide filler.

7. The pump diode assembly of claim 1, wherein the first substrate has a length greater than that of the emitter and the first substrate is configured to direct heat away from the emitter.

8. The pump diode assembly of claim 7, wherein the first substrate is configured to be cooled by one of a liquid and a gas.

9. The pump diode assembly of claim 1, further comprising a conductive layer disposed between the first substrate and the emitter and a conductive layer disposed between the second substrate and the emitter.

10. A pump diode assembly for a diode pumped laser, comprising:
a plurality of emitters, each of the plurality of emitters having a top side and a bottom side;
a first substrate configured to conduct heat away from the emitters, the first substrate including a plurality of substantially planar surfaces in contact with the top side of the emitters, the planar surfaces separated by a first plurality of grooves in the first substrate; and
a second substrate configured to conduct heat away from the emitters, the second substrate in contact with the bottom side of the emitters.

11. The pump diode assembly of claim 10, wherein the second substrate includes a plurality of substantially planar surfaces in contact with the bottom side of the emitters, the planar surfaces separated by grooves that align with the grooves in the first substrate.

12. The pump diode assembly of claim 10, further comprising an electrically conductive element disposed between the top side of the emitters and the first substrate and between the bottom side of the emitters and the second substrate.

13. The pump diode assembly of claim 10, wherein a groove in the plurality of grooves has a width that is smaller than that of a width of the emitter.

14. The pump diode assembly of claim 10, wherein the length of the first substrate extends beyond the emitter along the illumination axis of the emitter.

15. A method of manufacturing a pump diode assembly for a diode pumped laser, comprising:
depositing an conductive layer on a first substrate;
forming a first plurality of grooves through the conductive layer and partially through the first substrate;
placing a emitter on the conductive layer between two of the first plurality of grooves; and
placing a second substrate on the emitter such that the emitter is disposed between the first and second substrates.

16. The method of clam 15, further comprising:
depositing a conductive layer on the second substrate; and
forming a second plurality of grooves, complementary to the first plurality of grooves, partially through the second substrate;
wherein placing the second substrate on the emitter further comprises aligning the second plurality of grooves with the first plurality of grooves.

17. The method of claim 15, further comprising placing one of a second emitter and a thermally conductive spacer on the first conductive layer such that at least one of the first plurality of grooves is between and separates the first emitter and the one of a second emitter and a thermally conductive spacer.

18. The method of claim 15, further comprising at least partially filling a groove with a guide filler.

19. The method of claim 17, wherein the conductive layers are configured so that an electrical current will flow through each emitter in series.

20. The method of claim 17, wherein the conductive layers are configured so that an electrical current will flow through each emitter in parallel.
